(19) United States
(12) Patent Application Publication
(10) Pub. No.: US 2010/0134210 A1
(43) Pub. Date: Jun. 3, 2010

(54) Piezoelectric Resonator and Piezoelectric Filter Device

(75) Inventor: Keiichi Umeda, Yasu-shi (JP)

Correspondence Address: DICKSTEIN SHAPIRO LLP, 1633 Broadway, NEW YORK, NY, 10019, US

(73) Assignee: Murata Manufacturing Co., Ltd.

(21) Appl. No.: 12/683,092

(22) Filed: Jan. 6, 2010

Related U.S. Application Data
(63) Continuation of application No. PCT/JP2008/060131, filed on Jun. 2, 2008.

(30) Foreign Application Priority Data
Jul. 20, 2007 (JP) JP 2007-189901

(51) Int. Cl. H03H 9/205; H03H 9/17

(52) U.S. Cl. 333/189; 333/187

(57) ABSTRACT

A piezoelectric resonator includes an acoustic reflective layer including first acoustic impedance sub-layers made of a material with relatively low acoustic impedance and second acoustic impedance sub-layers made of a material with relatively high acoustic impedance. A thin-film laminate is disposed on the acoustic reflective layer. The thin-film laminate includes a piezoelectric thin-film, a first electrode, a second electrode greater than the first electrode, and a mass-adding film. The second electrode is disposed on the acoustic reflective layer. The mass-adding film is disposed in at least one portion of a region outside a piezoelectric vibrational section and extends around the first electrode. The second electrode extends over the piezoelectric vibrational section to a region containing the mass-adding film.

### CROSS REFERENCE TO RELATED APPLICATIONS

The present application is a continuation of International Application No. PCT/JP2008/060131, filed Jun. 2, 2008, and claims priority to Japanese Patent Application No. JP2007-189901, filed Jul. 20, 2007, the entire contents of each of these applications being incorporated herein by reference in their entirety.

### FIELD OF THE INVENTION

The present invention relates to piezoelectric resonators for use in, for example, oscillators, band-pass filters, and the like and also relates to piezoelectric filter devices. The present invention particularly relates to a piezoelectric resonator including a substrate and a thin-film laminate which includes a first electrode, a second electrode, and a piezoelectric thin-film disposed therebetween and which is disposed on the substrate and also relates to a piezoelectric filter device.

### BACKGROUND OF THE INVENTION

Conventional piezoelectric resonators and piezoelectric filter devices are known to include thin piezoelectric vibrational sections including piezoelectric thin-films.

For example, Patent Document 1 below discloses a piezoelectric filter shown in FIG. 25. The piezoelectric filter 501 includes a support substrate 502 having recessed portions 502a and 502b arranged on the upper surface thereof. In a region containing the recessed portion 502a, a first piezoelectric resonator 506 including a piezoelectric thin-film 503, an upper electrode 504, and a lower electrode 505 is disposed above the recessed portion 502a.

A piezoelectric resonator 509 including the piezoelectric thin-film 503, an upper electrode 507, and a lower electrode 508 is disposed above the recessed portion 502b.

The piezoelectric filter 501 has a ladder-type circuit configuration in which the piezoelectric resonators 506 and 509 are electrically connected to each other such that the piezoelectric resonator 506 serves as a series arm resonator and the piezoelectric resonator 509 serves as a parallel arm resonator. The lower electrode 505 of the piezoelectric resonator 506 is different in thickness from the lower electrode 508 of the piezoelectric resonator 509 and therefore there is a difference in resonant frequency between a series arm resonator and a parallel arm resonator.

Patent Document 2 below discloses a combination of a BAW resonator using a bulk wave and an acoustic reflector including layers made of a material with relatively low acoustic impedance and layers made of a material with relatively high acoustic impedance. A transverse wave leaking from the BAW resonator is reflected by the acoustic reflector such that the reflectivity of the transverse wave is close to the reflectivity of a longitudinal wave. Therefore, the BAW resonator has enhanced properties at the resonant frequency thereof.

Patent Document 1: Japanese Unexamined Patent Application Publication No. 2002-299980

Patent Document 2: Japanese Unexamined Patent Application Publication No. 2004-159339

Such a piezoelectric resonator including a thin-film laminate including a piezoelectric thin-film as disclosed in Patent Document 1 can be increased in resonant frequency as compared to those including piezoelectric plates with a relatively large thickness. Therefore, the piezoelectric resonator can be used to configure a piezoelectric filter device operating at higher frequencies in a thickness longitudinal vibration mode.

However, a spurious component is likely to be caused by a Lamb wave, other than the thickness longitudinal vibration mode, propagating in the transverse direction of the piezoelectric thin-film 503. Therefore, good resonant properties or filter properties cannot be achieved.

Patent Document 2 merely discloses the BAW resonator, which unlike the piezoelectric filter 501 uses a bulk wave. In order to enhance properties of the BAW resonator, which uses the bulk wave, at the resonant frequency thereof, the acoustic reflector is combined with the BAW resonator such that the reflectivity of the transverse wave is close to the reflectivity of a longitudinal wave.

### SUMMARY OF THE INVENTION

In view of the foregoing circumstances, it is an object of the present invention to provide a piezoelectric resonator which include a piezoelectric thin-film with a relatively small thickness, which can be used at high frequencies, and of which properties are hardly deteriorated by spurious modes propagating in the transverse direction of the piezoelectric thin-films and to provide a piezoelectric filter device.

The present invention provides a piezoelectric resonator including a substrate having a first principal surface and a second principal surface, an acoustic reflective layer which is disposed on the first principal surface and which includes first acoustic impedance sub-layers made of a material with relatively low acoustic impedance and second acoustic impedance sub-layers made of a material with relatively high acoustic impedance, and a thin-film laminate disposed on the acoustic reflective layer. The thin-film laminate includes a piezoelectric thin-film having a first principal surface and a second principal surface, a first electrode disposed on the first principal surface of the piezoelectric thin-film, a second electrode which is disposed on the second principal surface of the piezoelectric thin-film and which is greater than the first electrode, and a mass-adding film. The second electrode is disposed on the acoustic reflective layer. The first and second electrodes and a portion of the piezoelectric thin-film that is disposed therebetween form a piezoelectric vibrational section. The mass-adding film is disposed in at least one portion of a region outside the piezoelectric vibrational section and extends around the first electrode. The second electrode extends over the piezoelectric vibrational section to a region containing the mass-adding film in plan view.

In the piezoelectric resonator, the thickness of the first electrode may be the same as or different from the thickness of the second electrode. When the thickness of the second electrode is greater than the thickness of the first electrode, the wiring resistance of the second electrode can be reduced and therefore insertion loss can be improved.

The present invention provides a piezoelectric filter device including a plurality of piezoelectric resonators identical to the piezoelectric resonator. The substrate is common to the piezoelectric resonators. The piezoelectric resonators are electrically connected to each other so as to form a filter circuit. Since the piezoelectric filter device includes the piezoelectric resonators, ripples in the pass band of the piezoelectric filter device can be reduced and therefore the insertion loss can be reduced. In filter properties of the piezoelectric filter device, the steep of the pass band edge of the piezoelectric filter device, that is, the roll-off thereof is improved and the cutoff thereof is enhanced.

In the piezoelectric filter device, at least one of the piezoelectric resonators is preferably configured to be different from the other piezoelectric resonators. In this case, various pass bands can be readily formed when the piezoelectric resonators have different frequency properties.

In the piezoelectric filter device, the thickness of the second electrode of at least one of the piezoelectric resonators is preferably different from the thickness of the second electrode of each of the other piezoelectric resonators such that the resonant frequency of at least one of the piezoelectric resonators is different from the resonant frequency of each of the other piezoelectric resonators. The thickness of the second electrode of at least one of the piezoelectric resonators can be readily adjusted to be different from the thickness of the second electrode of each of the other piezoelectric resonators and therefore the resonant frequency of at least one of the piezoelectric resonators can be readily adjusted to be different from the resonant frequency of each of the other piezoelectric resonators.

In the piezoelectric filter device, the first electrode and second electrode of at least one of the piezoelectric resonators are preferably different in thickness from each other. Furthermore, the thickness of the second electrode of at least one of the piezoelectric resonators is preferably greater than the thickness of the first electrode thereof. In this case, the wiring resistance of the second electrode can be reduced and therefore insertion loss can be improved.

In a piezoelectric resonator according to the present invention, an energy confining-type piezoelectric vibrational section is disposed in a thin-film laminate including a piezoelectric thin-film. A relatively thin piezoelectric thin-film is used to form a piezoelectric vibrational section and therefore a reduction in thickness and an increase in frequency can be achieved.

The presence of a mass-adding film allows a mass to be added to a region around the piezoelectric vibrational section. A second electrode is greater than a first electrode and extends over the piezoelectric vibrational section to a region containing the mass-adding film. The second electrode is disposed opposite the mass-adding film and a mass is added to the piezoelectric thin-film from the mass-adding film and the second electrode. Therefore, spurious components due to vibrations propagating in the transverse direction of the piezoelectric thin-film can be effectively suppressed.

According to the present invention, an acoustic reflective layer is disposed on the second electrode side; hence, spurious components in a pass band can be effectively suppressed and the Q-factor can be increased.

The spurious components due to vibrations propagating in the transverse direction of the piezoelectric thin-film can be effectively suppressed and are very small. Good resonant properties can be achieved. The Q-factor of the piezoelectric resonator can be effectively increased.

### BRIEF DESCRIPTION OF THE DRAWINGS

FIG. 1(a) is a schematic front sectional view of a piezoelectric filter device according to a first embodiment of the present invention and FIG. 1(b) is circuit diagram showing the circuit configuration thereof.

FIGS. 2(a) to 2(c) are impedance Smith charts illustrating resonant properties of piezoelectric resonators, according to the first embodiment, each including a mass-adding film with a thickness of 0, 710, or 830 nm.

FIGS. 3(a) to 3(c) are impedance Smith charts illustrating resonant properties of piezoelectric resonators, according to the first embodiment, each including a mass-adding film with a thickness of 850, 880, or 940 nm.

FIGS. 4(a) and 4(b) are impedance Smith charts illustrating resonant properties of first piezoelectric resonators, according to the first embodiment, each including a mass-adding film with a thickness of 880 nm.

FIG. 5 is a schematic front sectional view of a region containing a first piezoelectric resonator according to the first embodiment.

FIGS. 6(a) to 6(d) are front sectional view illustrating steps of preparing the piezoelectric resonator-containing region shown in FIG. 5.

FIGS. 7(a) to 7(d) are front sectional view illustrating steps of preparing the piezoelectric resonator-containing region shown in FIG. 5.

FIGS. 8(a) to 8(d) are front sectional view illustrating steps of preparing the piezoelectric resonator-containing region shown in FIG. 5.

FIG. 9(a) is a side sectional view illustrating a step of preparing the piezoelectric resonator shown in FIG. 5 and FIG. 9(b) is front sectional view illustrating a step of preparing the piezoelectric resonator.

FIGS. 10(a) and 10(b) are front sectional views of modifications of the first piezoelectric resonator.

FIGS. 11(a) and 11(b) are front sectional views of modifications of the first piezoelectric resonator.

FIGS. 12(a) and 12(b) are impedance Smith charts illustrating resonant properties of first piezoelectric resonators, according to the first embodiment, each including a mass-adding film with a thickness of 850 nm.

FIGS. 13(a) to 13(c) are impedance Smith charts illustrating resonant properties of first piezoelectric resonators, according to the first embodiment, each including a mass-adding film with a thickness of 0, 460, or 490 nm.

FIGS. 14(a) to 14(c) are impedance Smith charts illustrating resonant properties of first piezoelectric resonators, according to the first embodiment, each including a mass-adding film with a thickness of 520, 580, or 670 nm.

FIGS. 15(a) and 15(b) are impedance Smith charts illustrating resonant properties of first piezoelectric resonators, according to the first embodiment, each including a mass-adding film with a thickness of 500 nm.

FIGS. 16(a) and 16(b) are impedance Smith charts illustrating resonant properties of first piezoelectric resonators, according to the first embodiment, each including a mass-adding film with a thickness of 0 or 850 nm.

FIGS. 17(a) to 17(f) are impedance Smith charts illustrating resonant properties of first piezoelectric resonators, according to the first embodiment, each including an uppermost SiO₂ film with a thickness of 600, 700, or 750 nm.

FIGS. 18(a) to 18(f) are impedance Smith charts illustrating resonant properties of first piezoelectric resonators, according to the first embodiment, each including an uppermost SiO₂ film with a thickness of 820, 850, or 870 nm.

FIGS. 19(a) to 19(f) are impedance Smith charts illustrating resonant properties of first piezoelectric resonators, according to the first embodiment, each including an uppermost SiO₂ film with a thickness of 900, 1000, or 1100 nm.

FIGS. 20(a) and 20(b) are impedance Smith charts illustrating resonant properties of first piezoelectric resonators, according to the first embodiment, each including a mass-adding film with a thickness of 500 nm.

FIGS. 21(a) and 21(b) are impedance Smith charts illustrating resonant properties of first piezoelectric resonators, according to the first embodiment, each including a mass-adding film with a thickness of 500 nm.

FIGS. 22(a) and 22(b) are schematic front sectional views of CSPs each including the piezoelectric filter device according to the present invention.

FIG. 23 is a schematic front sectional view of a CSP including the piezoelectric filter device according to the present invention.

FIGS. 24(a) and 24(b) are schematic front sectional views of CSPs each including the piezoelectric filter device according to the present invention.

FIG. 25 is a schematic front sectional view of an example of a conventional piezoelectric filter device.

### REFERENCE NUMERALS

1 piezoelectric filter device
2 substrate
2a upper surface
2b lower surface
3 and 4 piezoelectric resonators
5 acoustic reflective layer
5a to 5c first acoustic impedance sub-layers
5d and 5e second acoustic impedance sub-layers
6 thin-film laminate
7 acoustic reflective layer
8 thin-film laminate
9 piezoelectric thin-film
9a upper surface
9b lower surface
10 and 12 first electrodes
11 and 13 second electrodes
14 and 15 mass-adding films
14a inner edge
14b outer edge
16 protective film
21 and 22 tungsten films
23 and 24 metal films
25 and 26 wiring electrodes
31 piezoelectric resonator
32 mass-adding film
32a edge
32b side surface
33 piezoelectric resonator
34 mass-adding film
34a edge
34b side surface
35 and 37 piezoelectric resonators
36 and 38 mass-adding films
36a and 38a side surfaces

### DETAILED DESCRIPTION OF THE INVENTION

Embodiments of the present invention will now be described in detail with reference to the accompanying drawings such that the present invention becomes apparent.

### First Embodiment

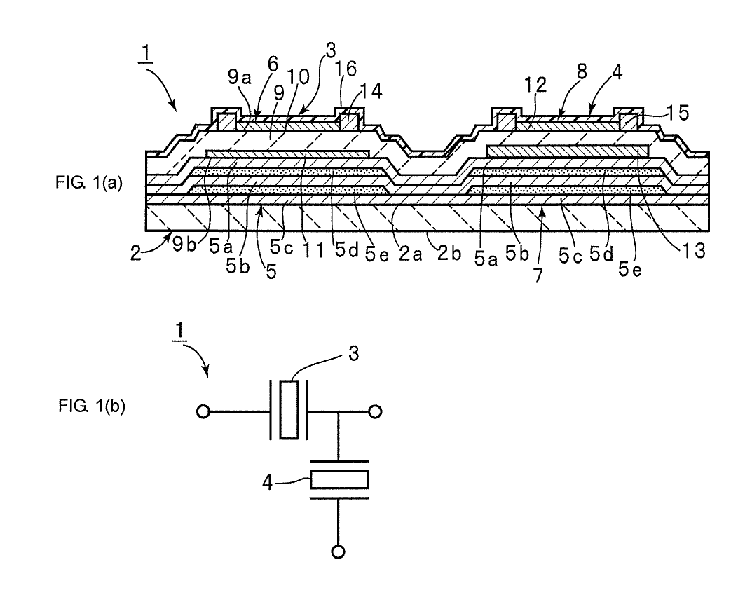

FIG. 1 is a front sectional view of a piezoelectric filter device according to a first embodiment of the present invention. The piezoelectric filter device 1 includes a substrate 2. The substrate 2 has an upper surface 2a that is a first principal surface and a lower surface 2b that is a second principal surface.

The substrate 2 is made of an appropriate insulating material. In particular, the substrate 2 is made of a semiconductor material such as Si, GaAs, GaN, or SiC; an insulating ceramic such as glass, alumina, sapphire, quartz, lithium tantalate, or lithium niobate; or a single-crystalline insulating resin. In this embodiment, the substrate 2 is made of high-resistivity Si (with a resistivity of 1000 Ω·cm or more).

In this embodiment, the single substrate 2 carries a plurality of piezoelectric resonators 3 and 4. That is, the substrate 2 is common to the piezoelectric resonators 3 and 4. The piezoelectric resonators 3 and 4 may be disposed above different substrates.

The piezoelectric filter device 1 is a piezoelectric filter with a ladder-type circuit configuration. As is well known, a ladder type of circuit includes a series arm resonator disposed in a series arm extending between an input terminal and an output terminal and also includes a parallel arm resonator disposed in a parallel arm connecting the series arm resonator to a ground potential. In the piezoelectric filter device 1, the piezoelectric resonator 3 serve as a series arm resonator and the piezoelectric resonator 4 serves as a parallel arm resonator. The piezoelectric resonators 3 and 4 are electrically connected to each other through a portion, which is not shown, and form a ladder circuit shown in FIG. 1(b).

With reference to FIG. 1(a), in a region containing the piezoelectric resonator 3, an acoustic reflective layer 5 and a thin-film laminate 6 are arranged on the substrate 2 in that order. In a region containing the piezoelectric resonator 4, an acoustic reflective layer 7 and a thin-film laminate 8 are arranged on the substrate 2 in that order. The acoustic reflective layer 5 has a layered structure in which first acoustic impedance sub-layers 5a to 5c made of a material with relatively low acoustic impedance and second acoustic impedance sub-layer 5d and 5e made of a material with relatively high acoustic impedance are alternately arranged. That is, the following layers are arranged from a piezoelectric vibrational section below toward the substrate 2 in this order: the first acoustic impedance sub-layer 5a, the second acoustic impedance sub-layer 5d, the first acoustic impedance sub-layer 5b, the second acoustic impedance sub-layer 5e, and the first acoustic impedance sub-layer 5c.

In the piezoelectric resonator 4, the acoustic reflective layer 7 as well as the acoustic reflective layer 5 is disposed. That is, the acoustic reflective layer 7 includes stacked first and second acoustic impedance sub-layers 5a to 5e. The following layers are arranged from a piezoelectric vibrational section below toward the substrate 2 in this order: the first acoustic impedance sub-layer 5a, the second acoustic impedance sub-layer 5d, the first acoustic impedance sub-layer 5b, the second acoustic impedance sub-layer 5e, and the first acoustic impedance sub-layer 5c.

The first acoustic impedance sub-layers 5a to 5c and the second acoustic impedance sub-layers 5d and 5e may be made of an appropriate organic or inorganic material.

The first acoustic impedance sub-layers 5a to 5c may be made of, for example, an inorganic material such as SiO₂ or SiOC or an organic or polymeric material such as a material, SU-8, commercially available from MicroChem Corporation, benzocyclobutene (BCB), or polyimide. The second acoustic impedance sub-layers 5d and 5e may be made of, for example, a metal such as W, Ir, Pt, or Mo; an inorganic compound such as AlN, SiN, Al₂O₃, or Ta₂O₅; or an appropriate organic material. In particular, a material for forming the first acoustic impedance sub-layers 5a to 5c is preferably a silicon oxide such as SiO₂ and a material for forming the second acoustic impedance sub-layers 5d and 5e is preferably W or Ta₂O₅. In order to enhance the adhesion between W and SiO₂ and/or the crystallinity of W, Ti and/or AlN sub-layers are preferably disposed between those sub-layers.

SiO₂ is preferably used to form the first acoustic impedance sub-layers 5a to 5c because the fluctuation in resonant frequency thereof due to temperature changes can be reduced. W is preferably used to form the second acoustic impedance sub-layers 5d and 5e because the acoustic impedance thereof is large and therefore the number of layers in an acoustic reflector can be reduced. Alternatively, Ta₂O₅ is preferably used to form the second acoustic impedance sub-layers 5d and 5e because Ta₂O₅ is an insulating material and therefore patterning is unnecessary.

In this embodiment, the three first acoustic impedance sub-layers 5a to 5c and the two second acoustic impedance sub-layers 5d and 5e are stacked in each of the acoustic reflective layers 5 and 7. The number of the first and second acoustic impedance sub-layers in each of the acoustic reflective layers 5 and 7 is not limited to five. The acoustic reflective layers 5 and 7 may each include at least one first acoustic impedance sub-layer and at least one second acoustic impedance sub-layer. The number of acoustic impedance sub-layers included in each of the acoustic reflective layers 5 and 7 is preferably four or more and more preferably five or seven.

The first acoustic impedance sub-layers, which have a relatively small acoustic impedance, need to be arranged on the piezoelectric vibrational section side and the second acoustic impedance sub-layers need to be arranged closer to the substrate than the first acoustic impedance sub-layers. This allows the acoustic reflective layers 5 and 7 to function such that vibrations propagating from the piezoelectric vibrational sections are reflected by the interfaces between the first and second acoustic impedance sub-layers; hence, spurious components in a pass band and insertion loss can be reduced.

The thin-film laminates 6 and 8 are disposed on the acoustic reflective layers 5 and 7, respectively, as described above. The thin-film laminate 6 includes a portion of a piezoelectric thin-film 9 which has an upper surface 9a that is a first principal surface and a lower surface 9b that is a second principal surface and which has a polarization axis aligned in the thickness direction thereof. In this embodiment, the piezoelectric thin-film 9 extends in the piezoelectric resonator 4. That is, in the piezoelectric resonator 4, the thin-film laminate 8 includes a portion of the piezoelectric thin-film 9.

The piezoelectric thin-film 9 is made of an appropriate piezoelectric single-crystal or ceramic exhibiting piezoelectricity. Examples of such a piezoelectric material include AlN, ZnO, LiNbO₃, LiTaO₃, KNbO₃, and lead zirconate titanate piezoelectric ceramics.

The piezoelectric thin-film 9 has a small thickness. The thickness thereof is not particularly limited and is about 200 to 5000 nm. Since the piezoelectric thin-film 9 has such a small thickness, the piezoelectric resonators 3 and 4 can be readily formed so as to operate at high frequencies.

In the piezoelectric resonator 3, a first electrode 10 is disposed on the upper surface 9a of the piezoelectric thin-film 9 and a second electrode 11 is disposed on the lower surface 9b of the piezoelectric thin-film 9. The first and second electrodes 10 and 11 are made of an appropriate conductive material. Examples of such a conductive material include metals such as Al, Pt, Au, Mo, W, Ti, Cr, Cu, Ru, Ir, and Ta and alloys of these metals. The first and second electrodes 10 and 11 may each include a plurality of stacked metal layers made of one of these metals or alloys.

In this embodiment, the first electrode 10, the second electrode 11, and a portion of the piezoelectric thin-film 9 that is disposed therebetween form the piezoelectric vibrational section. Therefore, when an alternating electric field is applied between the first and second electrodes 10 and 11, an electric field is applied to the piezoelectric vibrational section and therefore the piezoelectric vibrational section is excited. The piezoelectric vibrational section is a portion of the piezoelectric thin-film 9. Therefore, resonant properties using energy confining-type thickness longitudinal vibration can be obtained.

In this embodiment, the second electrode 11 has a plan area greater than that of the first electrode 10. In a lead wiring portion, an overlap between the first and second electrodes 10 and 11 has a parasitic capacitance; hence, the second electrode 11 has a notch such that there is no overlap between the first and second electrodes 10 and 11. The first electrode 10 is located in the second electrode 11 in plan view. In other words, the second electrode 11 extends outside the piezoelectric vibrational section.

In the piezoelectric resonator 4, a first electrode 12 and a second electrode 13 are arranged. In this embodiment, the piezoelectric resonator 3 is used as a series resonator and the piezoelectric resonator 4 is used as a parallel resonator. Therefore, the piezoelectric resonator 4, which is used as a parallel resonator, needs to have a relatively small resonant frequency; hence, the second electrode 13 has a thickness greater than that of the first electrode 12. In the piezoelectric resonator 4, the second electrode 13 is greater than the first electrode 12 and extends outside the piezoelectric vibrational section.

In the piezoelectric resonator 3, the thin-film laminate 6 includes a mass-adding film 14 which is disposed in at least one portion of a region outside the piezoelectric vibrational section and which extends around the first electrode 10. The second electrode 11 extends over the piezoelectric vibrational section to a region containing the mass-adding film 14 in plan view.

The mass-adding film 14, which is disposed in the region outside the piezoelectric vibrational section, is made of an appropriate material capable of adding a mass to the piezoelectric thin-film 9. Such a material may be insulating or conductive. In this embodiment, the mass-adding film 14 is ring-shaped and is in contact with the outer edge of the first electrode 10 and therefore is made of an insulating material. Examples of such an insulating material include AlN, Ta₂O₅, SiO₂, and SiN. AlN has a good mass-adding action and therefore is preferably used.

When the mass-adding film 14 is spaced from the first electrode 10, the mass-adding film 14 may be made of a metal such as Al or Pt or an alloy containing the metal. In this case, the first electrode 10 and the mass-adding film 14 are preferably made of the same material because manufacturing steps can be simplified.

In the piezoelectric resonator 4, a mass-adding film 15 is disposed in at least one portion of a region outside of the piezoelectric vibrational section. The mass-adding film 15 is made of substantially the same material as that used to form the mass-adding film 14. In the piezoelectric filter device 1, the mass-adding films 14 and 15 are preferably made of the same material because the number of types of materials used and the number of steps of a process can be reduced. Alternative, a material for forming the mass-adding film 14 may be different from a material for forming the mass-adding film 15. In this case, the mass-adding film 14 is preferably made of a material with an appropriate capability of adding a mass to the piezoelectric resonator 3 and the mass-adding film 15 is preferably made of a material with an optimum capability of adding a mass to the piezoelectric resonator 4. This allows the mass-adding capability of the mass-adding films 14 and 15 in the piezoelectric resonators 3 and 4 to be optimized.

The presence of the mass-adding films 14 and 15 is effective in suppressing spurious components from being caused by vibrations propagating in the transverse direction of the piezoelectric thin-film 9, which is spurious with respect to a thickness longitudinal vibration mode.

The shape of the mass-adding films 14 and 15 in plan view is not limited to a ring shape. The mass-adding films 14 and 15 may have various shapes. The mass-adding films 14 and 15 may be each formed in at least one portion of a region outside a corresponding one of the piezoelectric vibrational sections. In order to uniformly suppress spurious modes such as Lamb waves in outer regions of the piezoelectric vibrational sections, the mass-adding films preferably have, for example, a shape that is isotropic with respect to the center of each of the piezoelectric vibrational sections, that is, a circular ring shape.

The second electrodes 11 and 13 extend under the region containing the mass-adding film 14 and a region containing the mass-adding film 15, respectively. Therefore, the spurious components can be effectively suppressed by the mass-adding action of portions of the second electrodes 11 and 13 that extend under the regions containing the mass-adding films 14 and 15. Advantages obtained by the mass-adding action of the mass-adding films 14 and 15 and the second electrodes 11 and 13 are described below in detail with reference to experiments.

The length from the inner edge 14a to the outer edge 14b of the mass-adding film 14, that is, the width of the mass-adding film 14 is not particularly limited and is preferably 5 μm or more.

In this embodiment, the second electrodes 11 and 13 extend to regions under the mass-adding films 14 and 15. The second electrodes 11 and 13 may extend to portions of regions under the regions containing the mass-adding films 14 and 15.

In this embodiment, a protective film 16 extends over the first electrodes 10 and 12. The protective film 16 extends over not only the first electrodes 10 and 12 but also the mass-adding films 14 and 15, that is, the protective film 16 extends over the entire upper surface of piezoelectric filter device 1 except portions, disposed on the upper surface of the piezoelectric filter device 1, for electrically connecting or wiring the first electrodes 10 and 12 to the outside. The protective film 16 can protect structures located thereunder from being contaminated with moisture and impurities. The piezoelectric filter device 1 can be adjusted in frequency in such a manner that a material for forming the protective film 16 is selected, the thickness of the protective film 16 is adjusted, and/or the protective film 16 is etched in a step of forming the protective film 16.

The material for forming the protective film 16 is not particularly limited and may be SiO₂, SiN, AlN, or the like. The protective film 16 may include a plurality of stacked layers made of these materials. The protective film 16 may include a metal layer if the protective film 16 is prevented from being shorted with an electrode.

In the piezoelectric filter device 1, the mass-adding films 14 and 15 are each disposed in at least one portion of the region outside a corresponding one of the piezoelectric vibrational sections and the second electrodes 11 and 13 extend to the regions containing the mass-adding films 14 and 15, respectively, in plan view. Therefore, in resonant properties, a spurious component can be suppressed from being caused by a mode, such as a Lamb wave, propagating in the transverse direction of each of the piezoelectric thin-films. This allows the piezoelectric filter device 1 to have an increased Q-factor. Furthermore, ripples in a pass band and insertion loss can be reduced. The steep of the pass band edge of the filter is increased, the roll-off thereof is improved, and the cutoff thereof is enhanced. This is described below with reference to experiments.

A piezoelectric filter device 1 was prepared in such a manner that materials for films included in piezoelectric resonators 3 and 4 and the thickness of the films were set as shown in Table 1. The obtained piezoelectric filter device 1 had a ladder-type circuit configuration, the piezoelectric resonator 3 had a design resonant frequency of 1898 MHz, and the piezoelectric resonator 4 had a design resonant frequency of 1840 MHz.

TABLE 1
Thickness of each layer of resonators (nm)

| | Piezoelectric | Piezoelectric |
|---|---|---|
| | resonator 3 | resonator 4 |
| Protective/frequency-adjusting | 100 | 100 |
| film, SiO₂ | | |
| Adding film, AlN | 880 | 880 |
| Upper electrode, Al/W | 200/150 | 200/150 |
| Piezoelectric film, AlN | 1200 | 1200 |
| Lower electrode, W/Al | 150/200 | 180/200 |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| Resonant frequency (MHz) | 1898 | 1840 |
| 1-pF equivalent area (μm²) | 13600 | 13600 |

The acoustic impedance of SiO₂ is 1.2×10¹⁰ (g/s·m²). The acoustic impedance of W is 10.0×10¹⁰ (g/s·m²).

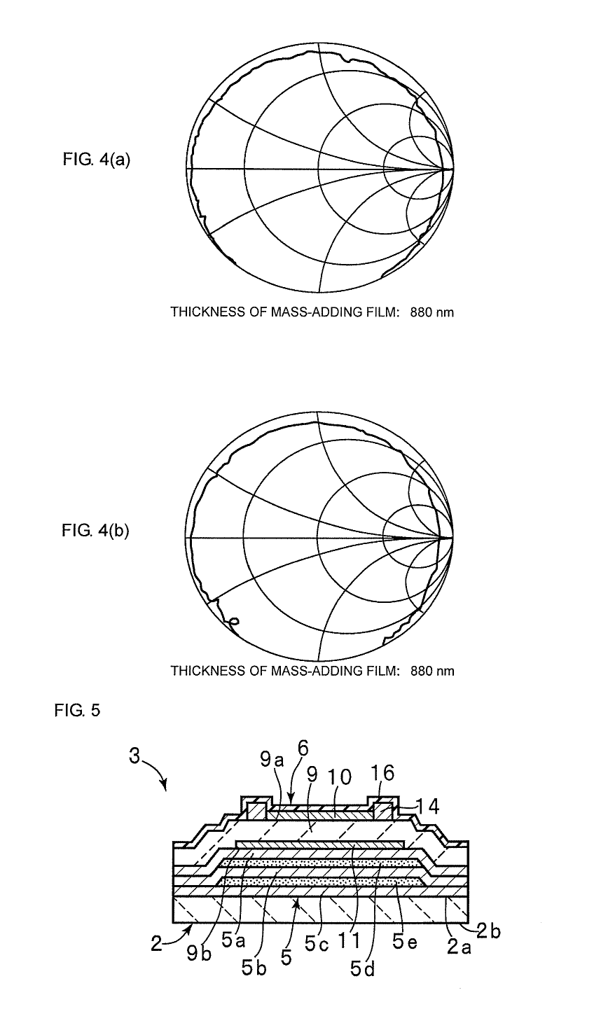

FIGS. 4(a) and 4(b) are impedance Smith charts illustrating resonant properties of the piezoelectric resonators 3 and 4 of the piezoelectric filter device 1 obtained as described above. The reason for using the impedance Smith charts instead of impedance-frequency properties is to clearly illustrate that a spurious component appears in a high pass band. As is clear from FIG. 4(a), in the piezoelectric resonator 3, substantially no spurious component appears in a high pass band. As is clear from FIG. 4(b), in the piezoelectric resonator 4, substantially no spurious component appears in a high pass band.

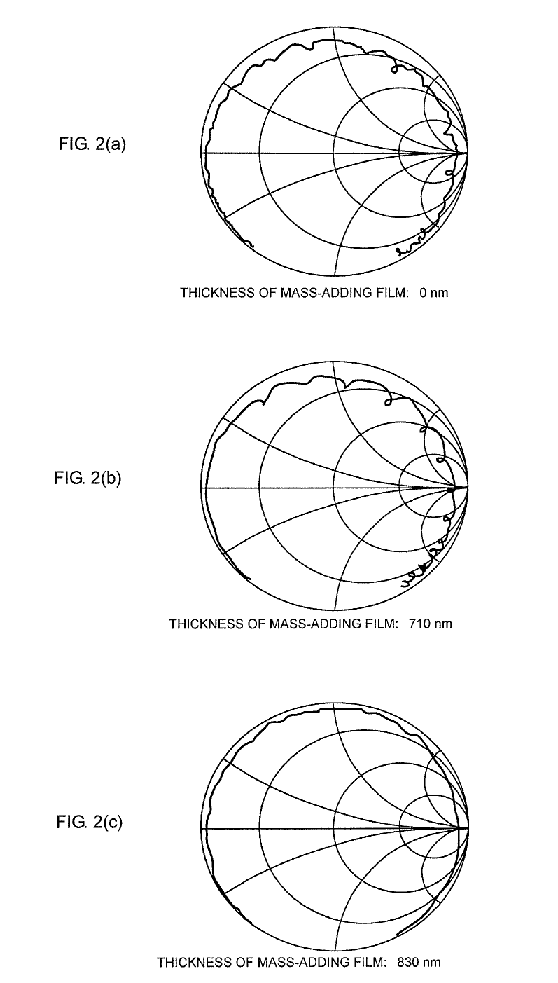

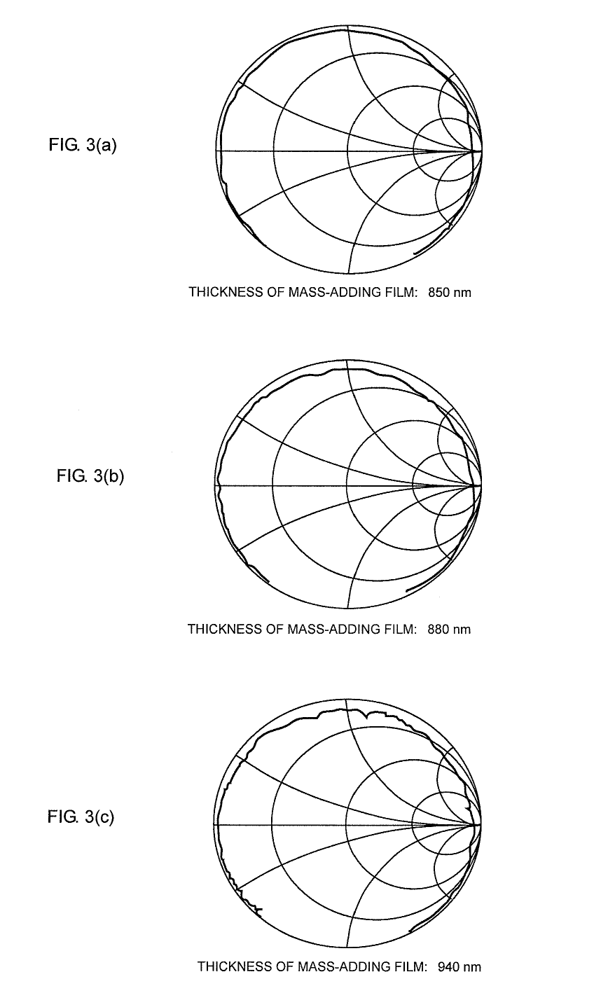

For comparison, the following resonators were prepared and then measured for resonant properties: a comparative piezoelectric resonator substantially identical in configuration to the piezoelectric resonator 3 except that the comparative piezoelectric resonator included no mass-adding film 14 and comparative piezoelectric resonators substantially identical in configuration to the piezoelectric resonator 3 except that the comparative piezoelectric resonators each included a mass-adding film 14 with a thickness of 710, 830, 850, 880, or 940 nm. FIGS. 2(a) to 2(c) and 3(a) to 3(c) show resonant properties of the comparative piezoelectric resonators each including the mass-adding film 14 with a thickness of 0, 710, 830, 850, 880, or 940 nm. As is clear from FIG. 2(a), in the comparative piezoelectric resonator including no mass-adding film 14, a large number of spurious components appear in a high pass band. In the comparative piezoelectric resonators each including the mass-adding film 14 with a thickness of 830 to 880 nm, spurious components can be effectively suppressed. That is, the presence of the mass-adding film 14 and the formation of a second electrode 11 extending to a region under the mass-adding film are effective in suppressing a spurious component.

The above spurious components scatter at an outer end portion of an electrode and therefore the Q-factor may be deteriorated. Furthermore, unnecessary vibrational energy is converted into thermal energy; hence, heat is generated and the dielectric strength is possibly reduced. In this embodiment, the spurious components can be effectively suppressed; hence, the Q-factor can be increased and the dielectric strength is hardly reduced.

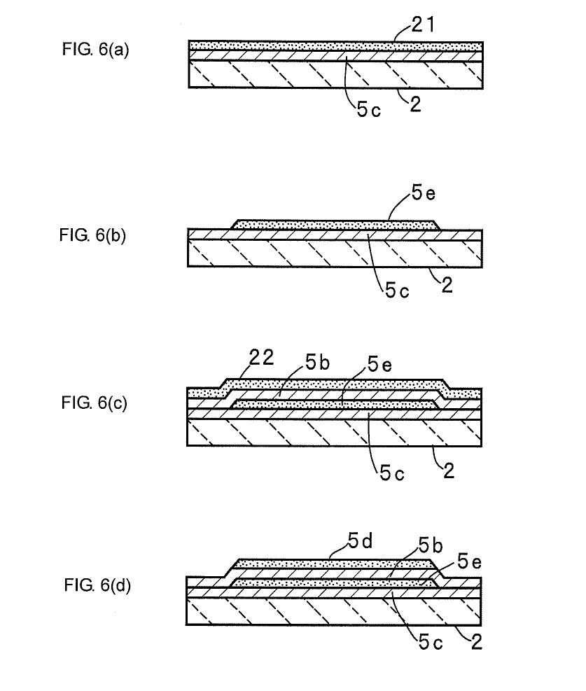

An exemplary process for manufacturing the piezoelectric filter device 1, which includes the piezoelectric resonators 3 and 4, will now be described with particular emphasis on the region containing the piezoelectric resonator 3. FIG. 5 is a front sectional view of the region containing the piezoelectric resonator 3 in the piezoelectric filter device 1. In order to prepare the piezoelectric resonator 3, the substrate 2 is prepared from Si as shown in FIG. 6(a). The first acoustic impedance sub-layer 5c is formed over the substrate 2 by the formation of thermal oxides or a sputtering or CVD process using SiO₂. A tungsten film 21 is formed over the first acoustic impedance sub-layer 5 by a sputtering or CVD process. As shown in FIG. 6(b), the tungsten film 21 is patterned by dry or wet etching, whereby the second acoustic impedance sub-layer 5e is formed. As shown in FIG. 6(c), the first acoustic impedance sub-layer 5b is formed from SiO₂ and a tungsten film 22 is then formed in the same manner as that described above.

As shown in FIG. 6(d), the tungsten film 22 is patterned by an etching process such as reactive ion etching or wet etching, whereby the second acoustic impedance sub-layer 5d is formed.

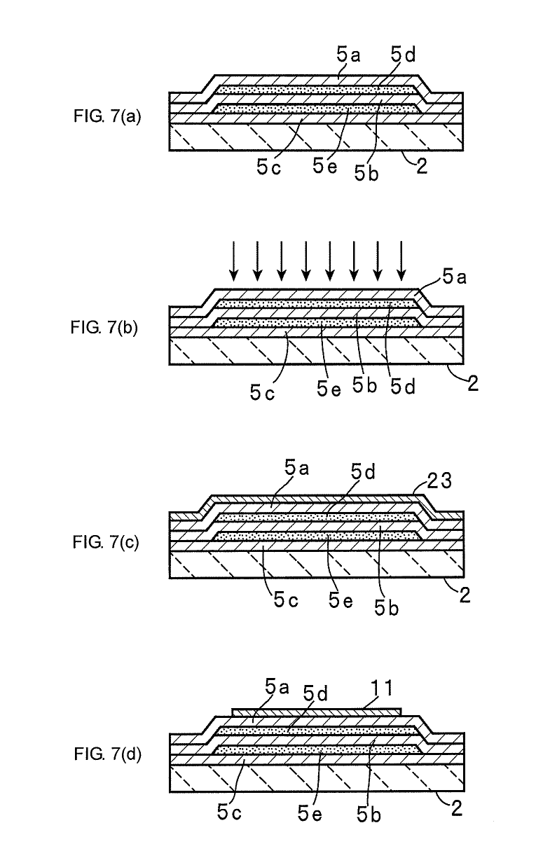

As shown in FIG. 7(a), the first acoustic impedance sub-layer 5a is by a sputtering or CVD process using SiO₂. As shown in FIG. 7(b), the first acoustic impedance sub-layer 5a is surface-planarized by Ar or oxygen plasma etching.

As shown in FIG. 7(c), a metal film 23 for forming the second electrode is formed over the first acoustic impedance sub-layer 5a by a sputtering or vapor deposition process.

As shown in FIG. 7(d), the metal film 23 is patterned by dry etching, wet etching, or a lift-off process, whereby the second electrode 11 is formed.

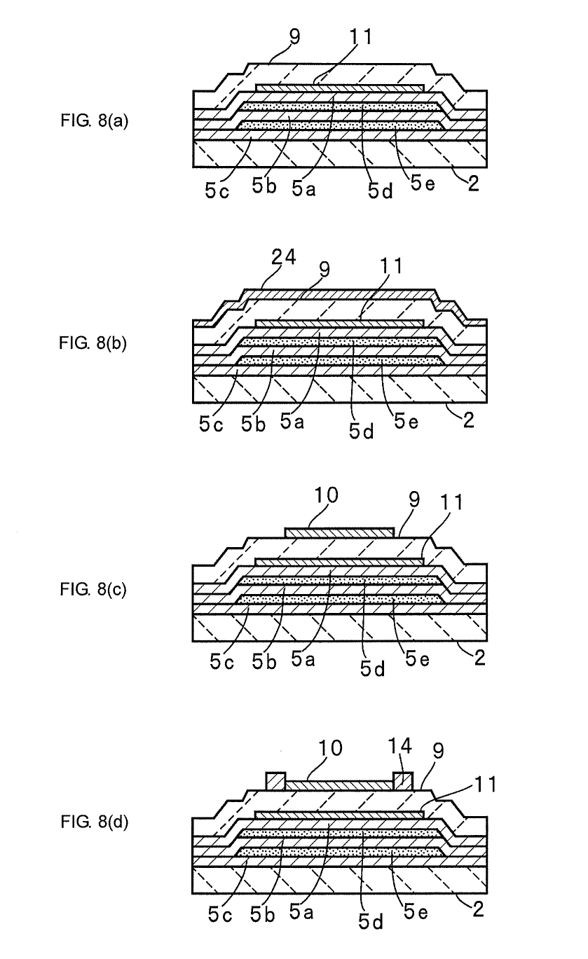

As shown in FIG. 8(a), AlN is deposited on the second electrode 11 by sputtering, whereby the piezoelectric thin-film 9 is formed.

As shown in FIG. 8(b), a metal film 24 is formed over the piezoelectric thin-film 9 by sputtering, vapor deposition, or the like. As shown in FIG. 8(c), the metal film 24 is patterned, whereby the first electrode 10 is formed. As shown in FIG. 8(d), AlN is deposited around the first electrode 10 by sputtering, whereby the mass-adding film 14 is formed.

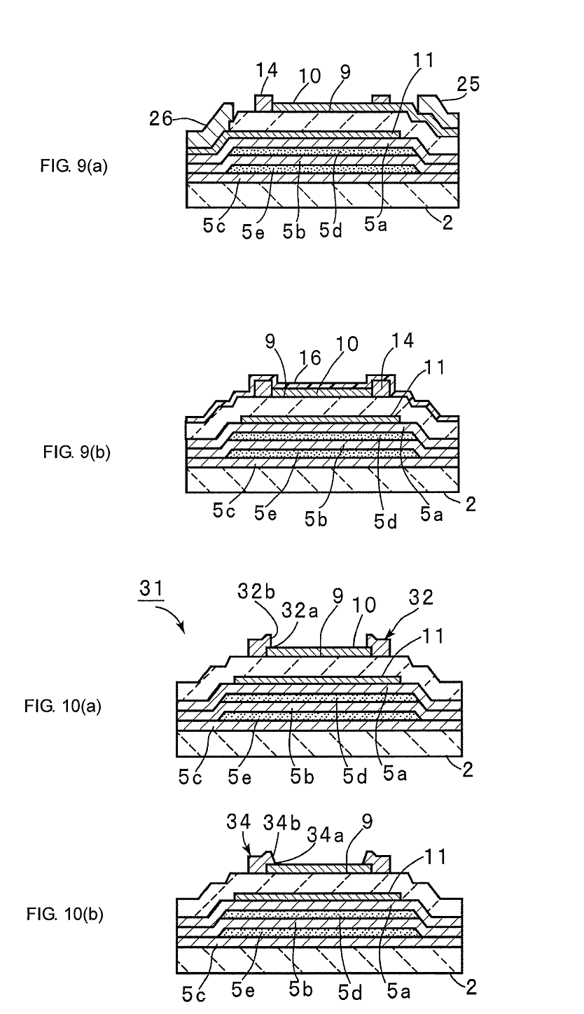

As shown in FIG. 9(a), wiring electrodes 25 and 26 are formed by sputtering, vapor deposition, or the like so as to be connected to the first electrode 10 and the second electrode 11. With reference to FIG. 9(a), which is a side sectional view, the first electrode 10 and the second electrode 11, which is disposed thereunder, each have an outer portion extending outside the piezoelectric vibrational section. The outer portion of the first electrode 10 and that of the second electrode 11 are connected to the wiring electrodes 25 and 26, respectively.

As shown in FIG. 9(b), which is a front sectional view, a layer of silicon dioxide, silicon nitride, or the like is deposited by a sputtering or CVD process and then patterned by an appropriate etching process such as RIE or wet etching, whereby the protective film 16 is formed. This provides the piezoelectric resonator 3 as shown in FIG. 5.

The piezoelectric resonator 4 can be prepared through substantially the same steps as those described above. In the piezoelectric resonators 3 and 4, the mass-adding films 14 and 15 are ring-shaped and are in contact with the outer edges of the first electrodes 10 and 12, respectively. The mass-adding films 14 and 15 may be varied in shape.

FIG. 10(a) shows a piezoelectric resonator 31 that is a modification. The piezoelectric resonator 31 includes a mass-adding film 32 which lies on a first electrode 10 such that the inner edge 32a of the mass-adding film 32 is located on the upper surface of the first electrode 10. FIG. 10(b) shows a piezoelectric resonator 33 that is a modification. The piezoelectric resonator 33 includes a mass-adding film 34 which lies on a first electrode such that the inner edge 34a of the mass-adding film 34 is located on the upper surface of the first electrode 10. The inner side surface 34b thereof is inclined such that a lower portion thereof extends toward the inside of a piezoelectric vibrational section. A side surface 32 of the mass-adding film 32 shown in FIG. 10(a) is not inclined but extends vertically.

The edges 32a and 34a of the mass-adding films 32 and 34 may extend on the first electrodes 10. In these structures, vibrations that should be suppressed readily propagate through the mass-adding films 32 and 34; hence, unnecessary vibrations can be effectively suppressed. Since the edges 32a and 34a thereof are located on the first electrodes 10, properties of these resonators hardly vary even if the edges 32a and 34a thereof are slightly misaligned during the formation of the mass-adding films 32 and 34.

Since the side surface 34b of the mass-adding film 34 is inclined as shown in FIG. 10(b), the mass-adding effect of the mass-adding film 34 gradually increases from the piezoelectric vibrational section toward the outside of the piezoelectric vibrational section. That is, the mass-adding effect thereof gently varies. Therefore, differences in properties are hardly caused even if the mass-adding film 34 is slightly misaligned in a step of forming the mass-adding film 34 by a photolithographic etching process.

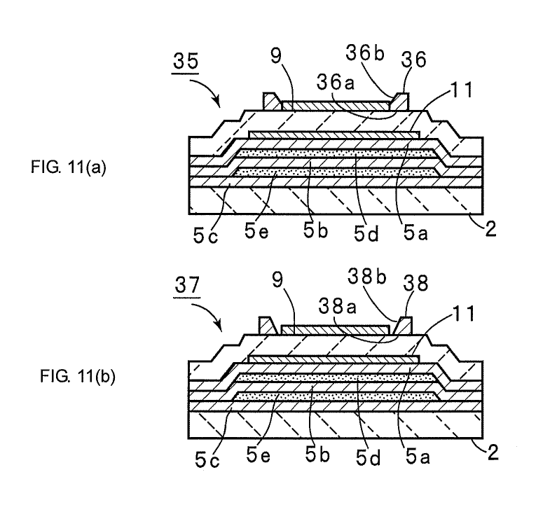

FIGS. 11(a) and 11(b) show a piezoelectric resonator 35 and a piezoelectric resonator 37, respectively. The piezoelectric resonators 35 and 37 include a mass-adding film 36 and a mass-adding film 38, respectively. Since the inner side surfaces 36b and 38b of the mass-adding films 36 and 38 are inclined, properties of these resonators hardly vary even if the inner edges 36a and 38a of the mass-adding films 36 and 38 are slightly misaligned.

The inner edges 36a and 38a of the mass-adding films 36 and 38 shown in FIGS. 11(a) and 11(b), respectively, are each located outside a first electrode 10. In the mass-adding film 36, the edge 36a thereof is in contact with the outer edge of the first electrode 10. The inner edge 38a of the mass-adding film 38 is spaced from the first electrode 10 as shown in FIG. 11(b).

### Second Embodiment

A piezoelectric filter device according to a second embodiment of the present invention has substantially the same configuration as that of the piezoelectric filter device 1 except that materials for forming members and the thickness of each member are as shown in Table 2. Since the piezoelectric filter device according to the second embodiment has substantially the same configuration as that of the piezoelectric filter device 1 according to the first embodiment, the same reference numerals as those described in the first embodiment are used for description.

TABLE 2
Thickness of each layer of resonators (nm)

| | Piezoelectric | Piezoelectric |
|---|---|---|
| | resonator 3 | resonator 4 |
| Protective/frequency-adjusting | 100 | 100 |
| film, SiO₂ | | |
| Adding film, AlN | 850 | 850 |
| Upper electrode, Al/W | 200/150 | 200/150 |
| Piezoelectric film, AlN | 1200 | 1200 |
| Lower electrode, W/Al | 150/200 | 150/200 |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| High-acoustic impedance | 690 | 690 |
| layer, W | | |
| Low-acoustic impedance layer, | 820 | 820 |
| SiO₂ | | |
| Resonant frequency (MHz) | 1898 | 1840 |
| 1-pF equivalent area (μm²) | 13600 | 13600 |

The piezoelectric filter device 1 according to the second embodiment includes a first piezoelectric resonator 3 and a second piezoelectric resonator 4. FIGS. 12(a) and 12(b) show the impedance Smith chart illustrating properties of the first piezoelectric resonator 3 and that of the second piezoelectric resonator 4, respectively. The piezoelectric resonators each have a thickness of 850 nm.

As is clear from FIGS. 12(a) and 12(b), in the first and second piezoelectric resonators 3 and 4, there are substantially no spurious components due to unnecessary vibrations.

### Third Embodiment

A piezoelectric filter device 1 was obtained in substantially the same manner as that described in the first embodiment except that materials for forming members and the thickness of each member were as shown in Table 3 below.

TABLE 3
Thickness of each layer of resonators (nm)

| | Piezoelectric | Piezoelectric |
|---|---|---|
| | resonator 3 | resonator 4 |
| Protective/frequency- | 100 | 100 |
| adjusting film, SiO₂ | | |
| Adding film, AlN | 500 | 500 |
| Upper electrode, | 100/10/60/10 | 100/10/60/10 |
| Al/Ti/Pt/Ti | | |
| Piezoelectric film, AlN | 1185 | 1185 |
| Lower electrode, | 10/60/10/100/10 | 10/60/10/200/10 |
| Ti/Pt/Ti/Al/Ti | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| Resonant frequency (MHz) | 2539 | 2468 |
| 1-pF equivalent area (μm²) | 12820 | 12820 |

The first piezoelectric resonator 3 serves as a series arm resonator and has a design resonant frequency of 2539 MHz. The second piezoelectric resonator 4 serves as a parallel arm resonator and has a design resonant frequency of 2468 MHz.

The thickness of each of first acoustic impedance sub-layers 5a to 5c and second acoustic impedance sub-layers 5d and 5e is equal to the quotient λ/4. The quotient λ/4 is given by the equation λ/4=v/4f, wherein v is the speed of sound in a material for forming each sub-layer and f is substantially equal to the resonant frequency of each piezoelectric resonator. The speed of sound in SiO₂ is about 6208 (m/s) and that in W is about 5221 (m/s). As is clear from Table 3, first electrodes 10 and 12 and second electrodes 11 and 13 each include a multilayer film including a plurality of metal layers shown in Table 3. Among the metal layers, Ti layers are used as adhesive layers for increasing the adhesion between the electrodes and the adhesion between the metal layers.

The thickness of the second electrode 13 is different from the thickness of the second electrode 11 and therefore the resonant frequency of the second piezoelectric resonator 4 is different from the resonant frequency of the first piezoelectric resonator 3.

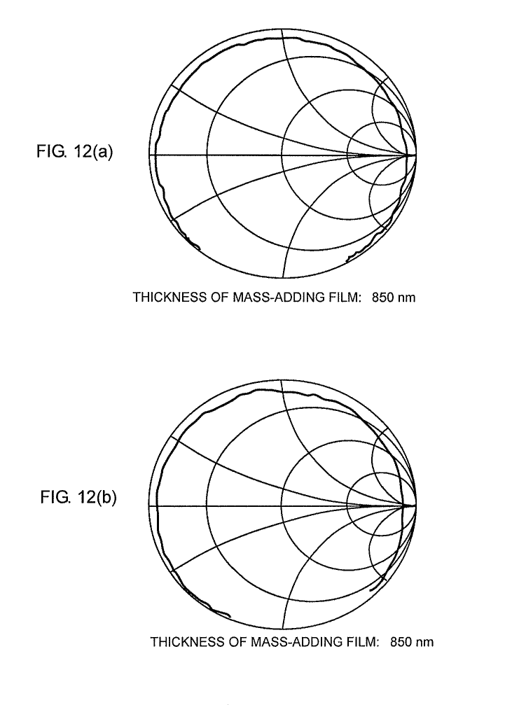

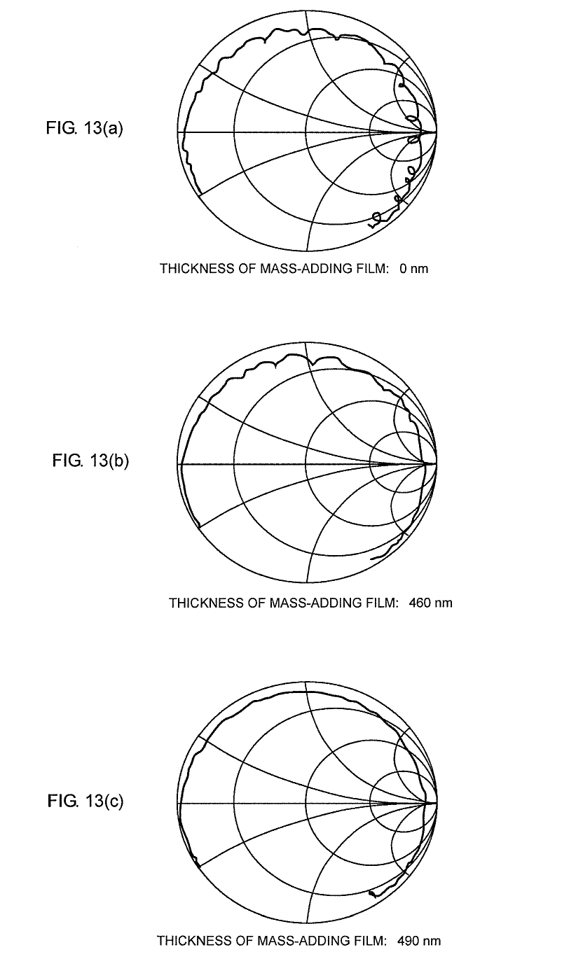

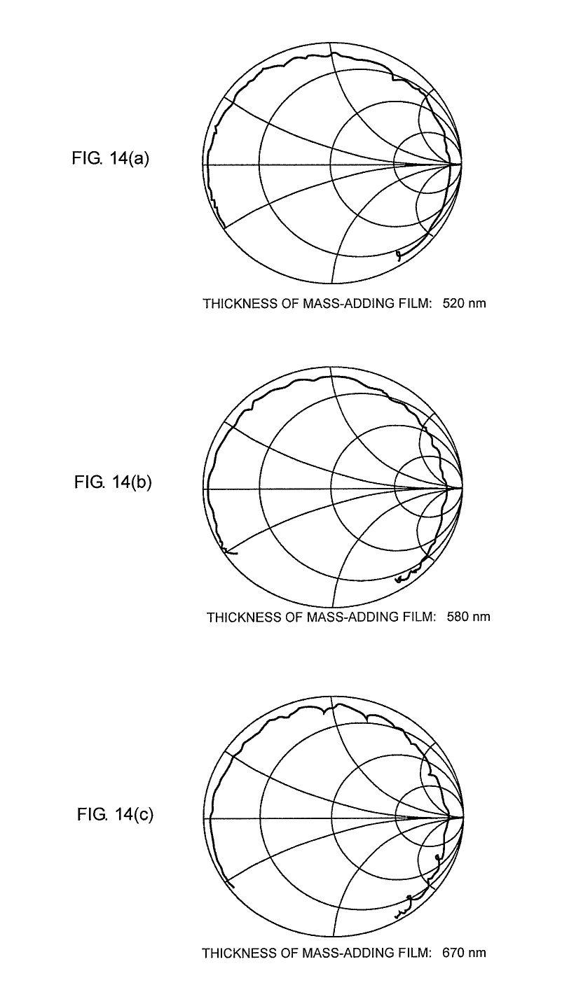

In this embodiment, piezoelectric resonators including mass-adding films each having a thickness of 0 (a comparative example including no mass-adding film), 460, 490, 520, 580, or 670 nm were prepared and then measured for resonant properties. FIGS. 13(a) to 13(c) and 14(a) to 14(c) show the measurement results. As is clear from FIGS. 13 and 14, spurious components due to unnecessary vibrations are effectively suppressed in the piezoelectric resonators including the mass-adding films in contrast to the piezoelectric resonator including no mass-adding film. In particular, the mass-adding films, made of AlN, having a thickness of 490 to 580 nm have substantially no spurious components and therefore are preferred.

FIGS. 15(a) and 15(b) are impedance Smith charts illustrating resonant properties of a first piezoelectric resonator 3 and second piezoelectric resonator 4, used in the piezoelectric filter device according to the third embodiment, including mass-adding film 14 and 15 with a thickness of 500 nm. As is clear from FIGS. 15(a) and 15(b), in this embodiment, undesired spurious components can be effectively suppressed in the piezoelectric resonators 3 and 4, which are operable in high frequency arrangements.

In this embodiment, a Pt film, an Al film, and Ti films serving as adhesive layers are arranged to form each of first electrodes 10 and 12 and second electrodes 11 and 13. The thickness of the Al film of the second electrode 11 is different from that of the second electrode 13 and therefore the piezoelectric resonators each have an adjusted resonant frequency. Since the resonant frequencies of the piezoelectric resonators 3 and 4 can be adjusted by adjusting the thickness of each of the Al films, which have relatively low density, the difference in resonant frequency between the piezoelectric resonators 3 and 4 can be readily and accurately adjusted so as to operate at high frequencies.

### Fourth Embodiment

A piezoelectric resonator 3 was prepared in substantially the same manner as that used to prepare the piezoelectric resonator 3 described in the first embodiment except that materials for forming members and the thickness of each member were as shown in Table 4 below.

TABLE 4
Thickness of each layer of resonators (nm)

| | Piezoelectric |
|---|---|
| | resonator 3 |
| Protective/frequency-adjusting film, SiO₂ | 0 |
| Adding film, AlN | 850 |
| Upper electrode, Al/W | 200/130 |
| Piezoelectric film, AlN | 1200 |
| Lower electrode, W/Al | 150/200 |
| Low-acoustic impedance layer, SiO₂ | 1000 |
| High-acoustic impedance layer, W | 500 |
| Low-acoustic impedance layer, SiO₂ | 500 |
| High-acoustic impedance layer, W | 500 |
| Low-acoustic impedance layer, SiO₂ | 2600 |
| Resonant frequency (MHz) | 1906 |
| 1-pF equivalent area (μm²) | 13600 |

The piezoelectric resonator 3 was prepared so as to operate in the 1900 MHz band and had a design resonant frequency of 1906 MHz. Electrode materials used were stacked metal films, that is, an Al film and a W film stacked thereon. In this embodiment, the thickness of each of first acoustic impedance sub-layers 5a to 5c and second acoustic impedance sub-layers 5d and 5e was deviated from the quotient λ/4. The quotient λ/4 is given by the equation λ/4=v/4f, wherein v is the speed of sound in a material for forming each acoustic impedance sub-layer and f is the resonant frequency of each piezoelectric resonator. The speed of sound in SiO₂ is 820 (m/s) and that in W is 690 (m/s).

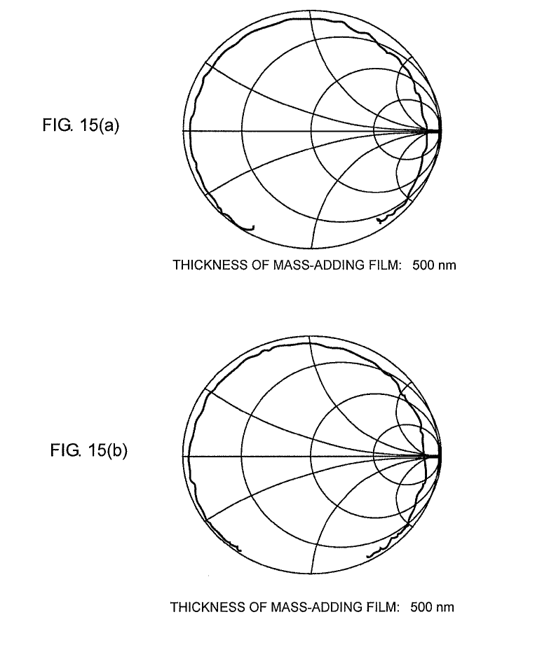

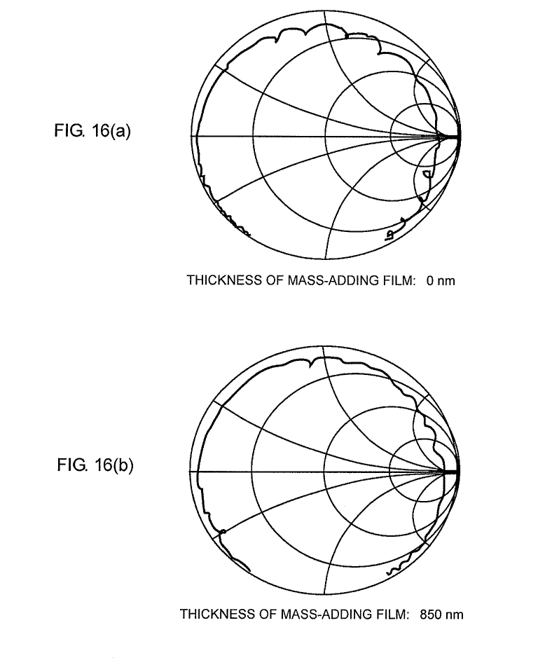

A comparative piezoelectric resonator was prepared in substantially the same manner as that used to prepare the piezoelectric resonator of this embodiment except that no mass-adding film was provided in the comparative piezoelectric resonator. FIG. 16(a) is an impedance Smith chart illustrating resonant properties of the comparative piezoelectric resonator. FIG. 16(b) is an impedance Smith chart illustrating resonant properties of the piezoelectric resonator of this embodiment.

As is clear from the comparison between FIGS. 16(a) and 16(b), the presence of a mass-adding film is effective in suppressing a spurious component.

In this embodiment, the first acoustic impedance sub-layer 5a is in contact with a thin-film laminate located at the top of a piezoelectric vibrational section and has a thickness of 1000 nm, that is, the first acoustic impedance sub-layer 5a is thicker than that described in the first embodiment. Therefore, a large amount of vibrational energy leaks from the first acoustic impedance sub-layer 5a; hence, frequency-temperature properties can be improved. Since an SiO₂ film has a positive temperature coefficient of frequency and an AlN film has a negative temperature coefficient of frequency, the absolute value of the entire thermal coefficient of frequency TCF can be reduced by increasing the thickness of the first acoustic impedance sub-layer 5a, which is made of SiO₂ and therefore has a positive temperature coefficient of frequency.

The second acoustic impedance sub-layer 5d, the first acoustic impedance sub-layer 5b, and the second acoustic impedance sub-layer 5e are thinner than those described in the first embodiment; hence, the reflectivity of transverse waves is increased. Therefore, the effect of confining the energy of thickness longitudinal vibration in a piezoelectric thin-film 9 is increased. This is because a transverse wave generated by the reflection of an acoustic wave incident on the outer periphery of a second electrode 11 or the interface between layers is securely reflected by an acoustic reflective layer 5 when being incident on the acoustic reflective layer 5. In general, the speed of a transverse wave propagating a solid is about one-half of that of a longitudinal wave. Therefore, the wavelength λs of the transverse wave is about half the wavelength λp of the longitudinal wave. In the case of manufacturing a λ/4 acoustic reflector, the reflector may have a thickness of λs/4 with respect to a longitudinal wave or a thickness of λp/4 to λp/8. That is, the reflectivity of a transverse wave can be increased when the thickness thereof is less than λ/4 with respect to a longitudinal wave.

### Fifth Embodiment

Piezoelectric resonators 3 were prepared in substantially the same manner as that described in the first embodiment except that materials for forming members and the thickness of each member were as shown in Table 5 below. The piezoelectric resonators had an operating frequency within the 1900 MHz band. The piezoelectric resonators included acoustic reflective layers including first acoustic impedance sub-layers 5a located at each of the acoustic reflective layers. The first acoustic impedance sub-layers 5a had a thickness X (nm) of 600 to 11000 nm. For comparison, comparative piezoelectric resonators were prepared in substantially the same manner as that used to prepare the piezoelectric resonators of this embodiment except that no mass-adding films were provided in the comparative piezoelectric resonators.

TABLE 5
Thickness of each layer of resonators (nm)

| | Piezoelectric |
|---|---|
| | resonators 3 |
| Protective/frequency-adjusting film, | 100 |
| SiO₂ | |
| Adding film, AlN | 850 |
| Upper electrode, Al/W | 200/150 |
| Piezoelectric film, AlN | 1200 |
| Lower electrode, W/Al | 150/200 |
| Low-acoustic impedance layer, SiO₂ | X |
| High-acoustic impedance layer, W | 690 |
| Low-acoustic impedance layer, SiO₂ | 820 |
| High-acoustic impedance layer, W | 690 |
| Low-acoustic impedance layer, SiO₂ | 820 |
| 1-pF equivalent area (μm²) | 13600 |

FIGS. 17(a), 17(c), and 17(e) are impedance Smith charts illustrating properties of the comparative piezoelectric resonators including no mass-adding films but first acoustic impedance sub-layers 5a with a thickness of 600, 700, or 750 nm. FIGS. 17(b), 17(d), and 17(f) are impedance Smith charts illustrating properties of the piezoelectric resonators including mass-adding films and the first acoustic impedance sub-layers 5a with a thickness of 600, 700, or 750 nm.

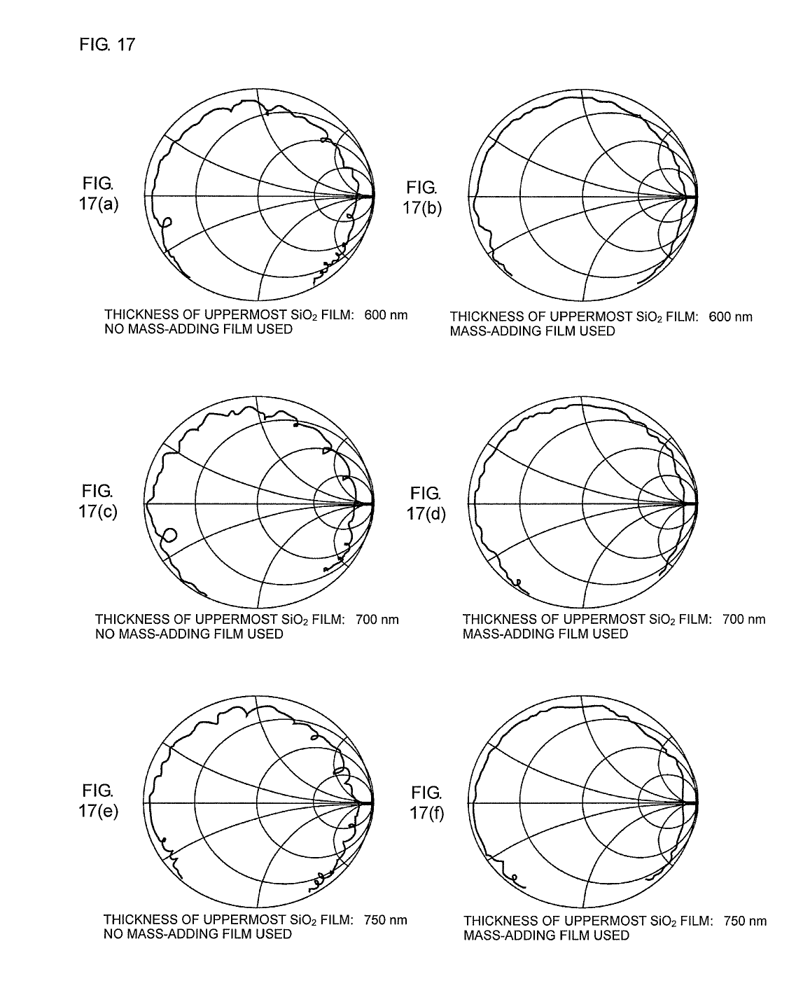

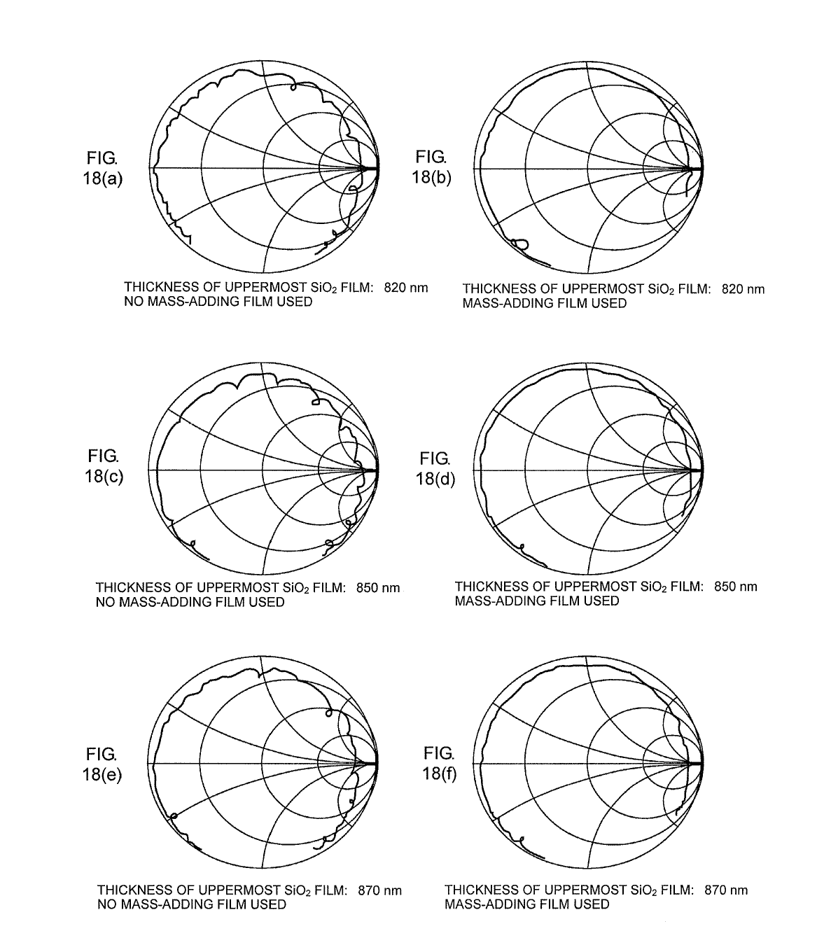

FIGS. 18(a), 18(c), and 18(e) are impedance Smith charts illustrating properties of the comparative piezoelectric resonators including first acoustic impedance sub-layers 5a with a thickness of 820, 850, or 870 nm. FIGS. 18(b), 18(d), and 18(f) are impedance Smith charts illustrating properties of the piezoelectric resonators including the first acoustic impedance sub-layers 5a with a thickness of 820, 850, or 870 nm.

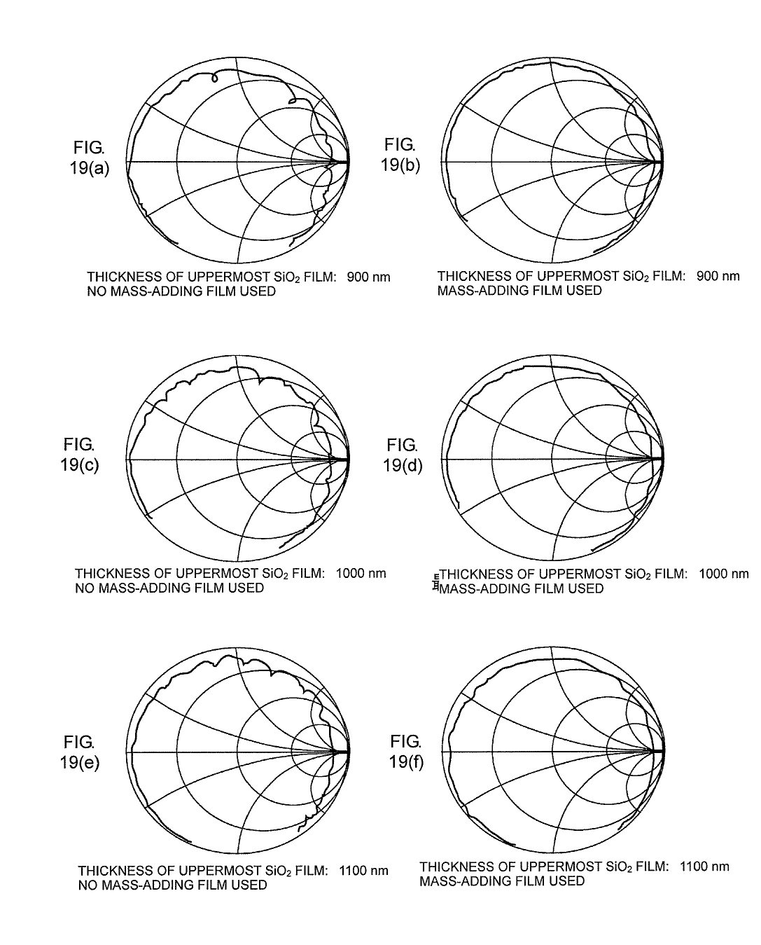

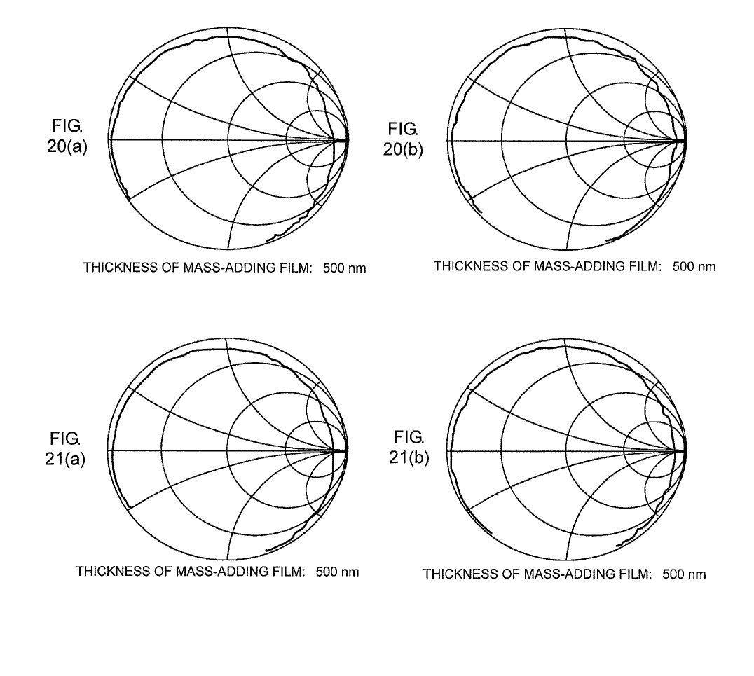

FIGS. 19(a), 19(c), and 19(e) are impedance Smith charts illustrating properties of the comparative piezoelectric resonators including first acoustic impedance sub-layers 5a with a thickness of 900, 1000, or 1100 nm. FIGS. 19(b), 19(d), and 19(f) are impedance Smith charts illustrating properties of the piezoelectric resonators including the first acoustic impedance sub-layers 5a with a thickness of 900, 1000, or 1100 nm.

As is clear from comparisons between FIGS. 17(a), 17(c), 17(e), 18(a), 18(c), 18(e), 19(a), 19(c), and 19(e) and FIGS. 17(b), 17(d), 17(f), 18(b), 18(d), 18(f), 19(b), 19(d), and 19(f), the presence of the mass-adding films is effective in suppressing spurious components.

The comparative piezoelectric resonators including the first acoustic impedance sub-layers 5a with a thickness of 800 nm or less have spurious components as shown in FIGS. 17(a), 17(c), 17(e), 18(a), 18(c), and 18(e). This means these comparative piezoelectric resonators have high-frequency cutoff dispersion properties.

On the other hand, the piezoelectric resonators including the first acoustic impedance sub-layers 5a with a thickness of 900 nm or more have no spurious components at frequencies less the their resonant frequencies thereof and therefore have low-frequency cutoff dispersion properties. Therefore, the presence of the mass-adding films is effective in suppressing spurious components in both the piezoelectric resonators having such high-frequency cutoff dispersion properties and the piezoelectric resonators having such low-frequency cutoff dispersion properties.

### Sixth Embodiment

A piezoelectric filter device 1 operating in the 2400 MHz band was prepared in accordance with specifications shown in Table 6 below.

TABLE 6
Thickness of each layer of resonators (nm)

| | Piezoelectric | Piezoelectric |
|---|---|---|
| | resonator 3 | resonator 4 |
| Protective/frequency- | 100 | 100 |
| adjusting film, SiO₂ | | |
| Adding film, AlN | 500 | 500 |
| Upper electrode, | 100/10/60/10 | 100/10/60/10 |
| Al/Ti/Pt/Ti | | |
| Piezoelectric film, AlN | 1185 | 1185 |
| Lower electrode, | 10/60/10/100/10 | 10/75/10/100/10 |
| Ti/Pt/Ti/Al/Ti | | |
| Low-acoustic impedance | 800 | 800 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| Resonant frequency (MHz) | 2424 | 2350 |
| 1-pF equivalent area (μm²) | 12820 | 12820 |

The difference between the resonant frequency of a first piezoelectric resonator and that of a second piezoelectric resonator is due to the difference between the thickness of a second electrode 11 and that of a second electrode 13. That is, Pt films have different thicknesses and therefore the first and second piezoelectric resonators have different resonant frequencies.

FIGS. 20(a) and 20(b) are impedance Smith charts illustrating resonant properties of the piezoelectric resonator 3 and the piezoelectric resonator 4, respectively, included in the piezoelectric filter device of this embodiment. As is clear from FIGS. 20(a) and 20(b), the piezoelectric resonators 3 and 4 have substantially no spurious components due to unnecessary vibrations. Second electrodes 11 and 13 that are lower electrodes include stacked metal films. Pt films among the stacked metal films are different in thicknesses from each other and the other films are identical in thickness to each other. This allows a difference in resonant frequency between the piezoelectric resonators 3 and 4 to be present.

### Seventh Embodiment

A piezoelectric filter device 1 operating in the 2400 MHz band was prepared in accordance with specifications shown in Table 7 below.

TABLE 7
Thickness of each layer of resonators (nm)

| | Piezoelectric | Piezoelectric |
|---|---|---|
| | resonator 3 | resonator 4 |
| Protective/frequency- | 100 | 100 |
| adjusting film, SiO₂ | | |
| Adding film, AlN | 500 | 500 |
| Upper electrode, | 100/10/60/10 | 100/10/60/10 |
| Al/Ti/Pt/Ti | | |
| Piezoelectric film, AlN | 1185 | 1185 |
| Lower electrode, | 10/60/10/100/10 | 10/60/10/200/10 |
| Ti/Pt/Ti/Al/Ti | | |
| Low-acoustic impedance | 800 | 800 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| High-acoustic impedance | 500 | 500 |
| layer, W | | |
| Low-acoustic impedance | 600 | 600 |
| layer, SiO₂ | | |
| Resonant frequency (MHz) | 2424 | 2365 |
| 1-pF equivalent area (μm²) | 12820 | 12820 |

The difference between the resonant frequency of a first piezoelectric resonator 3 and that of a second piezoelectric resonator 4 is due to the difference between the thickness of an Al film included in a second electrode 11 and that of an Al film included in a second electrode 13.

FIGS. 21(a) and 21(b) are impedance Smith charts illustrating resonant properties of the piezoelectric resonator 3 and the piezoelectric resonator 4, respectively. As is clear from FIGS. 21(a) and 21(b), the piezoelectric resonators 3 and 4 have substantially no spurious components due to unnecessary vibrations. This embodiment proves that the Al films of the second electrodes 11 and 13, which are lower electrodes, may have different thicknesses such that the piezoelectric resonators have different resonant frequencies.

### Eighth Embodiment

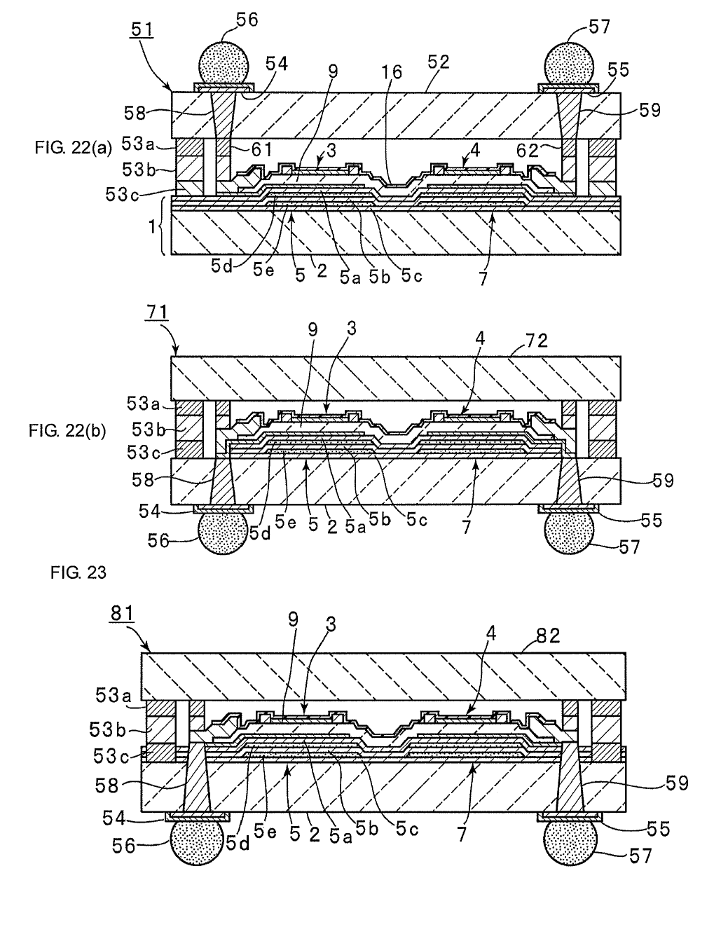

FIG. 22(a) is a schematic front sectional view of a CSP including the piezoelectric filter device 1 according to the first embodiment. The CSP (chip size package) 51 has a configuration in which a cover substrate 52 is disposed above the piezoelectric filter device 1 and is bonded to the piezoelectric filter device 1 with metal layers 53a to 53c so as to be opposite the piezoelectric resonators 3 and 4. The cover substrate 52 is disposed above the piezoelectric resonators 3 and 4 with a space therebetween such that the vibration of the piezoelectric resonators 3 and 4 is not prevented. The upper surface 52a of the cover substrate 52 carries electrode pads 54 and 55. The electrode pads 54 and 55 carry metal bumps 56 and 57, respectively, for surface mounting and are bonded thereto. The electrode pads 54 and 55 are connected to via-hole electrodes 58 and 59, respectively. The lower ends of the via-hole electrodes 58 and 59 are exposed at the lower surface 52b of the cover substrate 52. The lower ends of the via-hole electrodes 58 and 59 are electrically connected to the piezoelectric resonators 3 and 4, respectively, through junction electrodes 61 and 62, respectively.

The piezoelectric filter device 1 may be used in combination with the cover substrate 52 to form the CSP 51 as described above.

FIG. 22(b) shows a modified CSP 71 including the piezoelectric filter device 1 and a cover substrate 72. The cover substrate 72 has no via-hole electrodes or electrode pads. The substrate 2, which is included in the piezoelectric filter device 1, may have via-hole electrodes 58 and 59, electrode pads 54 and 55, and solder bumps 56 and 57. In the CSP 71, the substrate 2 can be used for surface mounting. The cover substrates 52 and 72 may be made of the same material as that used to form the substrate 2 or a material different from that used to form the substrate 2 and are preferably made of the same material.

The cover substrate 52 can be bonded to the substrate 2 with the metal layers 53a to 53c in such a manner that the metal layer 53a and the metal layer 53c are formed on the cover substrate 52 and the substrate 2, respectively, and then bonded to each other and metals are allowed to interdiffuse. That is, the metal layer 53a and the metal layer 53c are bonded to each other by a metal diffusion process in which a metal contained in the metal layer 53a and a metal contained in the metal layer 53c are allowed to interdiffuse such that the metal layer 53b is formed at the interface therebetween. When the metal layer 53a and the metal layer 53c are made of, for example, Sn and Cu, respectively, the metal layer 53b is made of a Sn—Cu alloy produced by the interdiffusion of Sn and Cu. An example of a combination of metals used for interdiffusion bonding may be a combination of the same type of metals such as Au and Au in addition to the combination of Sn and Cu. In this case, the metal layers 53a, 53b, and 53c are made of the same metal.

The CSP may be configured so as to be mounted on a printed circuit board by wire bonding without using solder bumps.

FIG. 23 shows a CSP 81 including piezoelectric resonators 3 and 4 and first acoustic impedance sub-layers 5a to 5c extending to side portions of regions containing the piezoelectric resonators 3 and 4. Via-hole electrodes may be formed so as to extend through the first acoustic impedance sub-layers.

### Ninth Embodiment

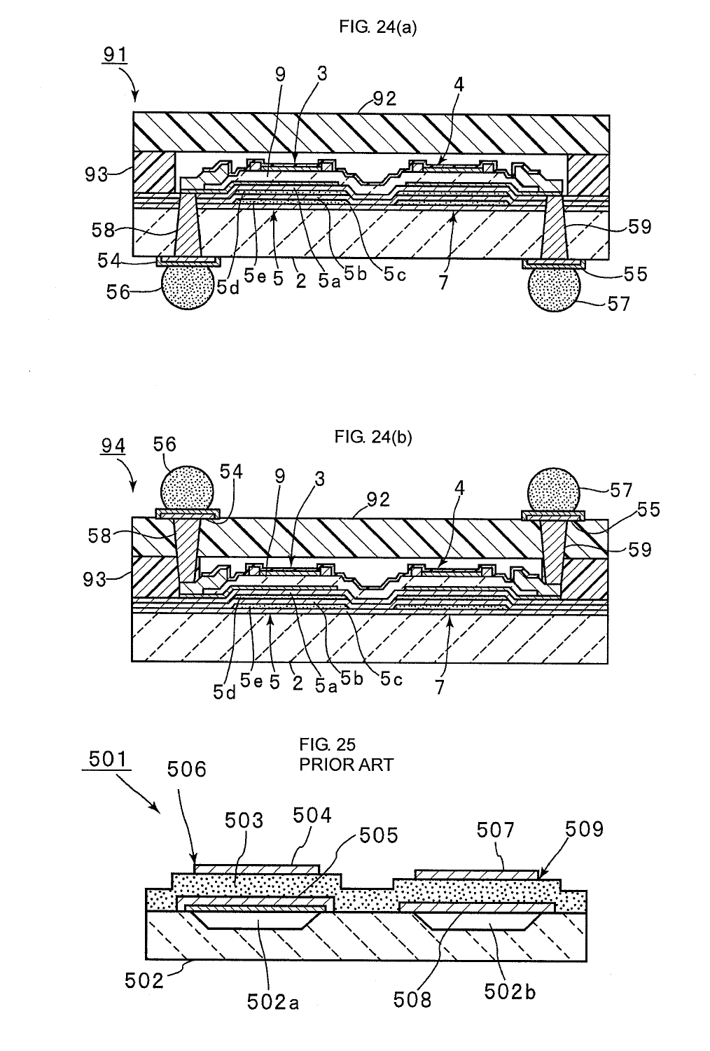

FIG. 24(a) shows a CSP 91 according to a ninth embodiment of the present invention. The CSP 91 does not include the cover substrate 72 shown in FIG. 24(a) but includes a synthetic resin layer 92. The synthetic resin layer 92 is made of an appropriate synthetic resin such as polyimide, SU-8, or BCB. The synthetic resin layer 92 is bonded to a substrate 2 with a synthetic resin layer 93 having a rectangular frame shape such that a space is formed under the synthetic resin layer 92 so as not prevent the vibration of piezoelectric resonators 3 and 4. The synthetic resin layer 93 is made of an appropriate synthetic resin such as polyimide, SU-8, or BCB. Alternatively, the synthetic resin layer 93 may be made of an adhesive.

Other members of the CSP 91 are substantially the same as those of the CSP shown in FIG. 24. As shown in FIG. 24(b), via-hole electrodes 58 and 59 may be arranged in a synthetic resin layer 92. The via-hole electrodes 58 and 59 extend through the synthetic resin layer 92 and a synthetic resin layer 93 having a rectangular frame shape.

In the CSPs 91 and 94 shown in FIGS. 24(a) and 24(b), respectively, the formation of the synthetic resin layers 92 and 93 is sufficient to make a CSP structure. This enables cost reduction.

1. A piezoelectric resonator comprising:
a substrate having a first principal surface and a second principal surface;
an acoustic reflective layer disposed on the first principal surface of the substrate, the acoustic reflective layer including first acoustic impedance sub-layers having a first acoustic impedance and second acoustic impedance sub-layers having a second acoustic impedance, the second acoustic impedance being higher than the first acoustic impedance;
a piezoelectric film having a first surface and a second surface;
a first electrode disposed on the first surface of the piezoelectric film;
a second electrode disposed on the second surface of the piezoelectric film and on the acoustic reflective layer, the second electrode being larger than the first electrode, the first and second electrodes and a portion of the piezoelectric film that is disposed therebetween forming a piezoelectric vibrational section; and
a mass-adding film disposed in at least one portion of a region outside the piezoelectric vibrational section and extending around the first electrode,
wherein the second electrode extends over the piezoelectric vibrational section to an area containing the mass-adding film.

2. The piezoelectric resonator according to claim 1, wherein a thickness of the first electrode is different from a thickness of the second electrode.

3. The piezoelectric resonator according to claim 2, wherein the thickness of the second electrode is greater than the thickness of the first electrode.

4. The piezoelectric resonator according to claim 1, wherein the first acoustic impedance sub-layers are selected from the group consisting of SiO₂, SiOC, benzocyclobutene, and polyimide.

5. The piezoelectric resonator according to claim 1, wherein the second acoustic impedance sub-layers are selected from the group consisting of W, Ir, Pt, Mo, AlN, SiN, Al₂O₃, and Ta₂O₅.

6. The piezoelectric resonator according to claim 1, wherein the first acoustic impedance sub-layers are SiO₂ and the second acoustic impedance sub-layers are W or Ta₂O₅.

7. The piezoelectric resonator according to claim 1, wherein the mass-adding film has a shape that is isotropic with respect to a center of the piezoelectric vibrational section.

8. The piezoelectric resonator according to claim 1, further comprising a protective film extending over the first electrode.

9. The piezoelectric resonator according to claim 8, wherein the protective film also extends over the mass-adding film.

10. The piezoelectric resonator according to claim 1, wherein an edge of the mass-adding film extends onto a surface of the first electrode.

11. The piezoelectric resonator according to claim 1, wherein an edge of the mass-adding film proximal to the first electrode is spaced from the first electrode.

12. A piezoelectric filter device comprising:
a plurality of piezoelectric resonators on the substrate, each of the plurality of piezoelectric resonators being the piezoelectric resonator according to claim 1,
wherein the plurality of piezoelectric resonators are electrically connected to each other so as to form a filter circuit.

13. The piezoelectric filter device according to claim 12, wherein at least one of the plurality of piezoelectric resonators is configured to be different from a remainder of the plurality of piezoelectric resonators.

14. The piezoelectric filter device according to claim 13, wherein a thickness of the second electrode of the at least one of the plurality of piezoelectric resonators is different from a thickness of the second electrode of each of the remainder of the plurality of piezoelectric resonators such that a resonant frequency of the at least one of the plurality of piezoelectric resonators is different from the resonant frequency of each of the remainder of the plurality of piezoelectric resonators.

15. The piezoelectric filter device according to claim 12, wherein a thickness of the first electrode and a thickness of the second electrode of at least one of the plurality of piezoelectric resonators are different from each other.

16. The piezoelectric filter device according to claim 15, wherein the thickness of the second electrode of the at least one of the plurality of piezoelectric resonators is greater than the thickness of the first electrode thereof.

17. The piezoelectric filter device according to claim 12, further comprising a cover disposed such that the plurality of piezoelectric resonators are positioned between the substrate and the cover.

18. The piezoelectric filter device according to claim 17, wherein the cover includes electrode pads.
